(19) United States
(12) Patent Application Publication
(10) Pub. No.: US 2002/0195057 A1
(43) Pub. Date: Dec. 26, 2002

(54) Apparatus for fabricating semiconductor structures and method of forming the same

(75) Inventors: Ravindranath Droopad, Chandler, AZ (US); Scott T. Massie, Bethlehem, PA (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL

(21) Appl. No.: 09/884,981

(22) Filed: Jun. 21, 2001

(51) Int. Cl. C23C 16/00; C23F 1/00; C30B 25/00

(52) U.S. Cl. 118/723 EB; 156/345.26; 118/715; 118/712

(57) ABSTRACT

An apparatus for forming a semiconductor structure is provided. The apparatus includes a chamber and a plurality of first material sources positioned at least partially within the chamber. The plurality of first material sources are configured to provide materials for the formation of a monocrystalline accommodating buffer layer on a substrate. The plurality of first material sources includes an oxygen source. At least one second material source is also positioned at least partially within the chamber and is configured to provide material for the formation of a monocrystalline oxygen-doped material layer overlying the monocrystalline accommodating buffer layer. The apparatus also includes an oxygen-adjustment mechanism configured to adjust the partial pressure of oxygen in the chamber.

### FIELD OF THE INVENTION

This invention relates generally to an apparatus for forming semiconductor structures having multiple epitaxial layers and to a method for their fabrication, and more specifically to a deposition equipment apparatus configured to form the structures and a method of using the apparatus to form the structures.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

Furthermore, the attempts to grow the monocrystalline films on a substrate often include forming multiple monocrystalline layers using separate, dedicated deposition reactors. For example, if a structure includes a first monocrystalline layer of a first type formed over a substrate and a second monocrystalline layer of a second type formed over the first monocrystalline layer, a first reactor is typically used to form the first layer and a second reactor is used to form the second layer.

The use of separate reactors to form the various monocrystalline layers is problematic for several reasons. In particular, the vacuum pressure attained for purposes of monocrystalline layer formation must be vented to ambient conditions to transport the substrates from one reactor to the next. When the substrates are exposed to the ambient conditions, the substrates are exposed to contaminants such as carbon, carbon dioxide, water vapor, and other oxidants present in the atmosphere. The contaminants and/or undesired oxidation may require additional processing to remove the material and/or may deleteriously affect properties such as electron transport and optical efficiency in subsequently grown films.

If a single-chamber apparatus was available for forming thin films of high quality monocrystalline material over substrates, capital expenditures for fabrication equipment could be reduced, as it may not be necessary to purchase multiple processing systems to produce the thin films. In addition, if thin films of high quality monocrystalline material could be formed on a bulk wafer in a single processing system, throughput could be increased and production costs could be reduced compared to formation of such films in conventional multi-chamber systems. Further, because the thin films would not be exposed to ambient conditions, the risk of contamination and/or undesired oxidation could be reduced and, accordingly, the integrity of the thin films could be maintained.

Accordingly, a need exists for a single-chamber semiconductor structure manufacturing apparatus that provides a single-chamber deposition system forming a monocrystalline oxygen-doped compound semiconductor film on a substrate.

### BRIEF DESCRIPTION OF THE DRAWINGS

The present invention is illustrated by way of example and not limitation in the accompanying figures, in which like references indicate similar elements, and in which:

FIG. 1 illustrates schematically an apparatus for fabricating semiconductor structures in accordance with the present invention;

FIGS. 2-4 illustrates schematically, in cross section, semiconductor structures formed using an embodiment of the apparatus of the present invention;

FIG. 5 illustrates a process for forming semiconductor structures using an embodiment of the apparatus of the present invention; and

FIGS. 6-16 illustrate schematically, in cross section, semiconductor structures formed using an embodiment of the apparatus of the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

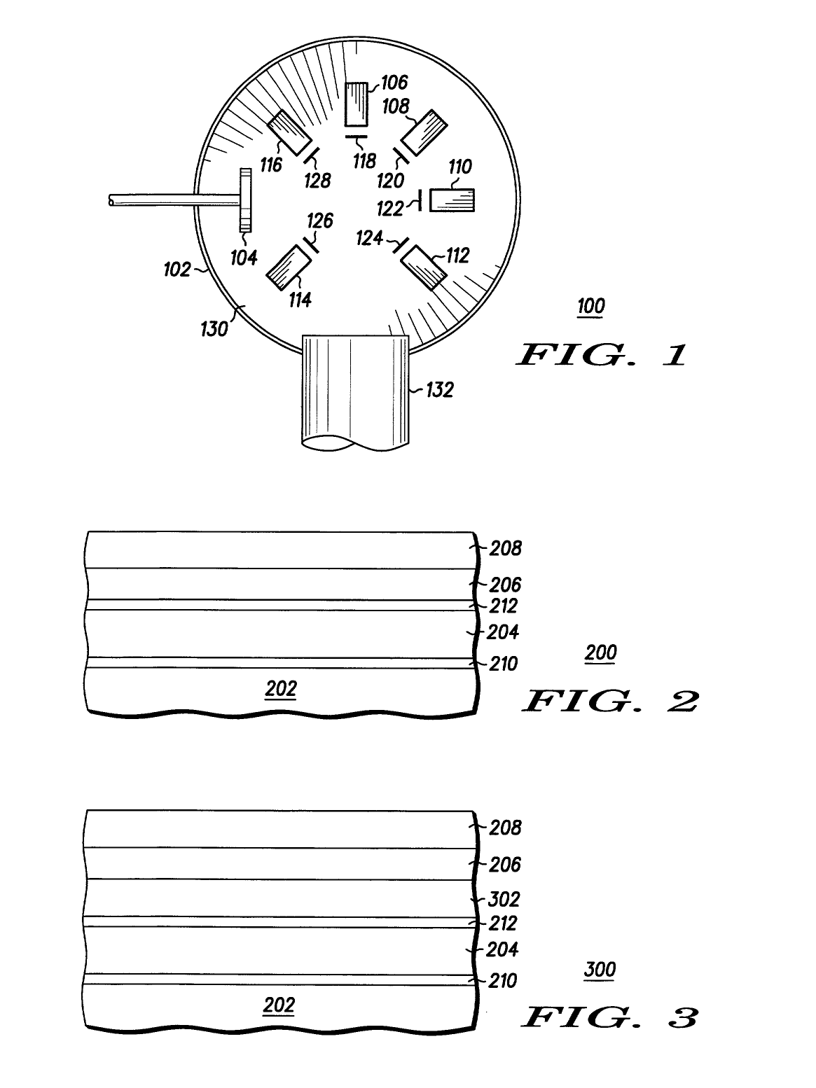

FIG. 1 schematically illustrates a single chamber system 100, configured to form semiconductor structures having multiple monocrystalline material layers, including a monocrystalline oxygen-doped compound semiconductor layer, in accordance with an exemplary embodiment of the invention. Single chamber system 100 includes a single chamber 102 having an interior 130 for the processing of semiconductor structures. As described in greater detail below, single chamber system 100 also includes a rotating manipulator 104, a plurality of first gaseous or elemental material sources 106-110, a plurability of second gaseous or elemental material sources 112-114, an oxygen source 116 and shutters 118-128. In addition, single chamber system 100 includes an oxygen adjustment system 132. In accordance with one embodiment of the invention, single chamber system 100 is a molecular beam epitaxy (MBE) reactor, wherein oxygen adjustment system 132 comprises a pump system. However, single chamber system 100 may also include other forms of deposition reactors such as a chemical vapor deposition (CVD) reactor, wherein oxygen adjustment system 132 comprises an inert gas purging system. Single chamber system 100 may also include metal organic chemical vapor deposition (MOCVD) reactors, migration enhanced epitaxy (MEE) reactors, atomic layer epitaxy (ALE) reactors, pulsed laser deposition (PLD) reactors, or the like, each with a suitable oxygen adjustment system.

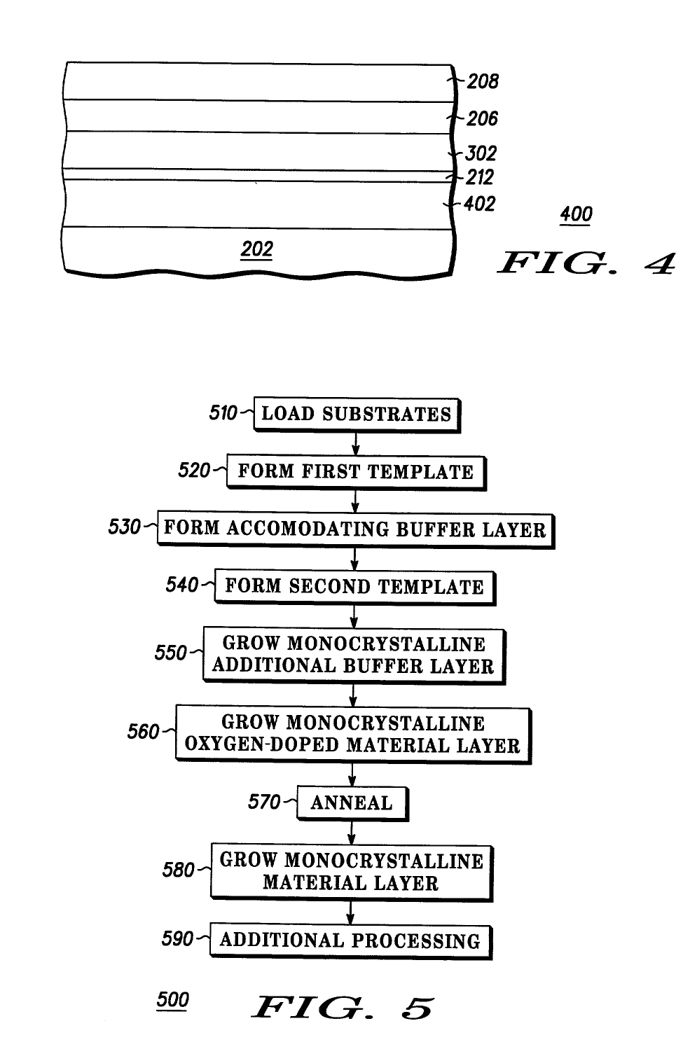

FIG. 2 schematically illustrates a semiconductor structure 200, which may be formed using a system in accordance with the present invention (e.g., system 100). Structure 200 includes a monocrystalline substrate 202, an accommodating buffer layer 204 comprising a monocrystalline material, a monocrystalline oxygen-doped material layer 206 and a monocrystalline material layer 208. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 200 also includes an amorphous interface layer 210 positioned between substrate 202 and accommodating buffer layer 204. Structure 200 may also include a template layer 212 between the accommodating buffer layer and monocrystalline oxygen-doped material layer 206 and/or a template layer (not shown) between the substrate and the accommodating buffer layer. As will be explained more fully below, the template layers help to initiate the growth of a monocrystalline material layer overlying another layer.

Substrate 202, in accordance with an embodiment of the invention, is a monocrystalline semiconductor or compound semiconductor wafer, preferably of large diameter such as, for example, at least approximately 200 mm in diameter and possibly at least approximately 300 mm in diameter. The wafer can be of, for example, a material from Group IV of the periodic table, and preferably a material from Group IVB, e.g., Carbon, Silicon, etc. Examples of Group IV semiconductor materials include silicon, germanium, mixed silicon and germanium, mixed silicon and carbon, mixed silicon, germanium and carbon, and the like. Preferably substrate 202 is a wafer containing silicon or germanium, and most preferably is a high quality monocrystalline silicon wafer as used in the semiconductor industry. Accommodating buffer layer 204 is preferably a monocrystalline oxide material epitaxially grown on the underlying substrate. In accordance with one embodiment of the invention, amorphous interface layer 210 is grown on substrate 202 at the interface between substrate 202 and the growing accommodating buffer layer 204 by the oxidation of substrate 202 during the growth of layer 204. The amorphous interface layer serves to relieve strain that might otherwise occur in the monocrystalline accommodating buffer layer 204 as a result of differences in the lattice constants of the substrate and the buffer layer. As used herein, lattice constant refers to the distance between atoms of a unit cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline oxygen-doped material layer 206 and, hence, monocrystalline material layer 208.

Accommodating buffer layer 204 is preferably a monocrystalline oxide material selected for its crystalline compatibility with the underlying substrate and with the overlying material layer. For example, the material could be an oxide having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Most of these materials are insulators, although strontium ruthenate, for example, is a conductor. Generally, these materials are metal oxides, and more particularly, these metal oxides typically include at least two different metallic elements. In some specific applications, the metal oxides may include three or more different metallic elements.

Amorphous interface layer 210 is preferably an oxide formed by the oxidation of the surface of substrate 202, and more preferably is composed of a silicon oxide. The thickness of layer 210 is sufficient to relieve strain attributed to mismatches between the lattice constants of substrate 202 and accommodating buffer layer 204. Typically, layer 210 has a thickness in the range of approximately 0.5-5 nm.

The material for monocrystalline material layer 208 can be selected, as desired, for a particular structure or application. For example, the monocrystalline material of layer 208 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe), and the like. Monocrystalline material layer 208 may also comprise other semiconductor materials, metals, or other materials which are used in the formation of semiconductor structures, devices and/or integrated circuits.

Monocrystalline oxygen-doped material layer 206 may comprise any of those material layers that comprise monocrystalline material layer 208 and that are substantially lattice matched to monocrystalline material layer 208. Preferably, monocrystalline oxygen-doped material layer 206 is formed of the same compound semiconductor material that comprises monocrystalline material layer 208 and serves as a seed layer for the subsequent growth of monocrystalline material layer 208. The oxygen content of monocrystalline oxygen-doped material layer 206 may range from about 10¹⁵/cm² to about 10¹⁷/cm². Monocrystalline oxygen-doped material layer 206 is highly resistive and may tend to reduce backgating and sidegating in FET devices. In addition, monocrystalline oxygen-doped material layer 206 may facilitate isolation of CMOS devices present in the substrate from devices formed in monocrystalline material layer 208 and may facilitate isolation of semiconductor devices formed in layer 208 from other devices formed in layer 208. Moreover, oxygen-doped compound semiconductor materials, such as oxygen-doped AlGaAs, may increase the radiation hardness of compound semiconductor devices formed on silicon and thus may be used in deep space applications. Layer 206 may have a thickness in the range of from about 5 nm to about 500 nm, and preferably has a thickness in the range of from about 100 nm to about 250 nm.

Appropriate materials for the template layer 212 are discussed below. Suitable template materials chemically bond to the surface of an underlying layer at selected sites and provide sites for the nucleation of the epitaxial growth of an overlying material layer. When used, the template layers have a thickness ranging from about 1 to about 10 monolayers.

FIG. 3 illustrates, in cross section, a portion of a semiconductor structure 300 in accordance with a further embodiment of the invention. Structure 300 is similar to the previously described semiconductor structure 200, except that an additional monocrystalline oxygen-doped buffer layer 302 is positioned between accommodating buffer layer 204 and monocrystalline oxygen-doped material layer 206. In one embodiment, the additional oxygen-doped buffer layer may be positioned between template layer 212 and the overlying layer of monocrystalline oxygen-doped material 206. The additional buffer layer, formed of a oxygen-doped compound semiconductor material when the monocrystalline oxygen-doped material layer 206 comprises a compound semiconductor material, serves to provide a lattice compensation when the lattice constant of the accommodating buffer layer cannot be adequately matched to the overlying monocrystalline oxygen-doped compound semiconductor material layer.

FIG. 4 schematically illustrates, in cross section, a portion of a semiconductor structure 400 in accordance with another exemplary embodiment of the invention. Structure 400 is similar to structure 300, except that structure 400 includes an amorphous layer 402, rather than monocrystalline accommodating buffer layer 204 and amorphous interface layer 210.

As explained in greater detail below, amorphous layer 402 may be formed by first forming a monocrystalline accommodating buffer layer 204 and an amorphous interface layer 210 in a similar manner to that described above with reference to semiconductor structure 300 of FIG. 3. Additional oxygen-doped buffer layer 302 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 402 formed in this manner comprises materials from both the accommodating buffer and interface layers, which amorphous layers may or may not amalgamate. Thus, layer 402 may comprise one or two amorphous layers. Formation of amorphous layer 402 between substrate 202 and additional oxygen-doped buffer layer 302 relieves stresses between layers 202 and 302 and provides a true compliant substrate for subsequent processing—e.g., monocrystalline oxygen-doped material layer 206 formation.

The processes previously described above in connection with FIGS. 2 and 3 are adequate for growing monocrystalline material layers over a monocrystalline substrate. However, the process described in connection with FIG. 4, which includes transforming a monocrystalline accommodating buffer layer to an amorphous oxide layer, may be better for growing monocrystalline material layers because it allows any strain in layer 302 to relax.

In accordance with one embodiment of the present invention, additional oxygen-doped buffer layer 302 serves as an anneal cap during layer 402 formation and as a template for subsequent monocrystalline oxygen-doped material layer 206 formation. Accordingly, layer 302 is preferably thick enough to provide a suitable template for layer 206 growth (at least one monolayer) and thin enough to allow layer 302 to form as a substantially defect free monocrystalline oxygen-doped material.

The following non-limiting, illustrative examples illustrate various combinations of materials useful in structures 200, 300 and 400 in accordance with various alternative embodiments of the invention. These examples are merely illustrative, and it is not intended that the invention be limited to these illustrative examples.

### EXAMPLE 1

In accordance with one embodiment of the invention, monocrystalline substrate 202 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 204 is a monocrystalline layer of Sr_{z}Ba_{1-z}TiO₃ where z ranges from 0 to 1 and the amorphous interface layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 206. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 208 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline oxygen-doped compound semiconductor material layer 206 is an oxygen-doped compound semiconductor layer of gallium arsenide (GaAs) or aluminum gallium arsenide (AlGaAs) having a thickness of about 5 nm to about 500 nm and preferably a thickness of about 100 nm to 250 nm.

Monocrystalline material layer 208 is a non-oxygen-doped compound semiconductor layer of GaAs if layer 206 is a layer of oxygen-doped GaAs or of AlGaAs if layer 206 is a layer of oxygen-doped AlGaAs. Monocrystalline material layer 208 has a thickness of about 1 nm to about 100 micrometers (μm) and preferably a thickness of about 0.5 μm to 10 μm. The thickness generally depends on the application for which the layer is being prepared. To facilitate the epitaxial growth of the oxygen-doped gallium arsenide or aluminum gallium arsenide on the monocrystalline oxide accommodating buffer layer, a template layer is formed by capping the accommodating buffer layer. The template layer is preferably 1-10 monolayers of Ti-As, Sr-O-As, Sr-Ga-O, or Sr-Al-O. By way of a preferred example, 1-2 monolayers of Ti-As or Sr-Ga-O have been illustrated to successfully grow GaAs layers.

### EXAMPLE 2

In accordance with a further embodiment of the invention, monocrystalline substrate 202 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700° C. The lattice structure of the resulting crystalline oxide exhibits a 45° rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP). Monocrystalline oxygen-doped compound semiconductor layer 206 formed of one these materials may have a thickness of about 5 nm to about 500 nm, and preferably a thickness in the range of from about 100 nm to about 250 nm, and non-oxygen-doped monocrystalline material layer 208 formed of one of these materials may have a thickness of about 1.0 nm to 10 μm. A suitable template for this structure is 1-10 monolayers of zirconium-arsenic (Zr-As), zirconium-phosphorus (Zr-P), hafnium-arsenic (Hf-As), hafnium-phosphorus (Hf-P), strontium-oxygen-arsenic (Sr-O-As), strontium-oxygen-phosphorus (Sr-O-P), barium-oxygen-arsenic (Ba-O-As), indium-strontium-oxygen (In-Sr-O), or barium-oxygen-phosphorus (Ba-O-P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr-As template. A monocrystalline layer of the compound semiconductor material from the indium phosphide system is then grown on the template layer in the presence of oxygen. The resulting lattice structure of the oxygen-doped compound semiconductor material exhibits a 45° rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. The II-VI compound semiconductor material for both the oxygen-doped compound semiconductor layer and the monocrystalline material layer can be, for example, zinc selenide (ZnSe) or zinc sulfur selenide (ZnSSe). A suitable template for this material system includes 1-10 monolayers of zinc-oxygen (Zn-O) followed by 1-2 monolayers of an excess of zinc followed by the selenidation of zinc on the surface. Alternatively, a template can be, for example, 1-10 monolayers of strontium-sulfur (Sr-S) followed by the ZnSeS.

### EXAMPLE 4

This embodiment of the invention is an example of structure 300 illustrated in FIG. 3. Substrate 202, accommodating buffer layer 204, monocrystalline oxygen-doped material layer 206 and monocrystalline material layer 208 can be similar to those described in example 1. In addition, an additional oxygen-doped buffer layer 302 serves to alleviate strains that might result from a mismatch of the crystal lattice of the accommodating buffer layer and the lattice of the monocrystalline oxygen-doped material layer 206. Buffer layer 302 can be an oxygen-doped layer of germanium (Ge) or GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) oxygen-doped strain compensated superlattice. In accordance with one aspect of this embodiment, buffer layer 302 includes an oxygen-doped GaAsₓP₁₋ₓ superlattice, wherein the value of x ranges from 0 to 1. In accordance with another aspect, additional oxygen-doped buffer layer 302 includes an oxygen-doped In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline oxygen-doped material which in this example is an oxygen-doped compound semiconductor material. The compositions of other compound semiconductor materials, such as those listed above, may also be similarly varied to manipulate the lattice constant of layer 302 in a like manner. The superlattice can have a thickness of about 50-500 nm and preferably has a thickness of about 100-200 nm. The template for this structure can be the same of that described in example 1. Alternatively, additional oxygen-doped buffer layer 302 can be an oxygen-doped layer of monocrystalline Ge having a thickness of 1-50 nm and preferably having a thickness of about 2-20 nm. In using a germanium buffer layer, a template layer of either germanium-strontium (Ge-Sr) or germanium-titanium (Ge-Ti) having a thickness of about one monolayer can be used as a nucleating site for the subsequent growth of the monocrystalline oxygen-doped material layer which in this example is formed of a compound semiconductor material. The formation of the accommodating buffer layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 300 as illustrated in FIG. 3. Substrate material 202, accommodating buffer layer 204, monocrystalline oxygen-doped material layer 206, monocrystalline material layer 208 and template layer 212 can be the same as those described above in example 2. In addition, additional oxygen-doped buffer layer 302 is inserted between the accommodating buffer layer and the overlying monocrystalline oxygen-doped material layer. The additional oxygen-doped buffer layer, a further monocrystalline material which in this instance comprises a semiconductor material, can be, for example, an oxygen-doped graded layer of indium gallium arsenide (InGaAs) or indium aluminum arsenide (InAlAs). In accordance with one aspect of this embodiment, additional buffer layer 302 includes oxygen-doped InGaAs, in which the indium composition varies from 0 to about 50%. The additional buffer layer 302 preferably has a thickness of about 10-30 nm. Varying the composition of the additional buffer layer from GaAs to InGaAs serves to provide a lattice match between the underlying monocrystalline oxide material and the overlying layer of monocrystalline oxygen-doped material which in this example is an oxygen-doped compound semiconductor material. Such an additional buffer layer is especially advantageous if there is a lattice mismatch between accommodating buffer layer 204 and monocrystalline oxygen-doped material layer 206.

### EXAMPLE 6

This example provides exemplary materials useful in structure 400, as illustrated in FIG. 4. Substrate material 202, template layer 212, monocrystalline oxygen-doped material layer 206 and monocrystalline material layer 208 may be the same as those described above in connection with example 1.

Amorphous layer 402 is an amorphous oxide layer which is suitably formed of a combination of amorphous interface layer materials (e.g., layer 210 materials as described above) and accommodating buffer layer materials (e.g., layer 204 materials as described above). For example, amorphous layer 402 may include a combination of SiOₓ and Sr_{z}Ba_{1-z}TiO₃ (where z ranges from 0 to 1), which combine or mix, at least partially, during an anneal process to form amorphous oxide layer 402.

The thickness of amorphous layer 402 may vary from application to application and may depend on such factors as desired insulating properties of layer 402, type of monocrystalline material comprising layer 206, and the like. In accordance with one exemplary aspect of the present embodiment, layer 402 thickness is about 2 nm to about 100 nm, preferably about 2-10 nm, and more preferably about 5-6 nm.

Layer 302 comprises a monocrystalline oxygen-doped material that can be grown epitaxially over a monocrystalline oxide material such as material used to form accommodating buffer layer 204. In accordance with one embodiment of the invention, layer 302 includes the same materials as those comprising layer 206. For example, if layer 206 includes oxygen-doped GaAs, layer 302 includes an oxygen-doped GaAs. However, in accordance with other embodiments of the present invention, layer 302 may include materials different from those used to form layer 206. In accordance with one exemplary embodiment of the invention, layer 302 is about 5 nm to about 500 nm thick.

Referring again to FIG. 1, system 100 may be used to form the structures illustrated above in FIGS. 2-4. In particular, the accommodating buffer layer, the amorphous interface layer, any template layers, and the monocrystalline oxygen-doped material layer may be grown or deposited, and optional anneal and/or other processing steps may be performed, in a single chamber. Thus, multiple high quality epitaxial layers may be formed on a substrate using a system in accordance with the present invention.

By way of example, structure 200 may be formed using system 100 by forming accommodating buffer layer 204, amorphous oxide layer 210, template layer 212 and monocrystalline oxygen-doped material layer 206 in chamber 102. Monocrystalline material layer 208 (e.g., a non-oxygen-doped GaAs layer) may be subsequently formed in another deposition system. Accommodating buffer layers and oxygen-doped compound semiconductor layers are preferably formed in chambers different from those used for the formation of non-oxygen-doped compound semiconductor layers because reactants such as oxygen used to form the accommodating buffer layer and oxygen-doped layers may deleteriously affect properties of subsequently formed non-oxygen-doped compound semiconductor or other material layers. For example, oxygen may degrade the desired opto-electronic properties of GaAs.

Referring to FIG. 1 in greater detail, a rotating manipulator 104 is at least partially positioned within chamber 102 and is configured to hold and rotate a wafer. Rotating manipulator 104, along with chamber 102, may be configured to handle wafers of various sizes, and in accordance with one embodiment of the invention, rotating manipulator 104 and chamber 102 are designed to process wafers having a diameter of up to about 300 mm. Rotating manipulator 104 is further configured to heat the wafer to a temperature up to at least about 750° C., with temperature variation over the wafer of about one to two percent. Furthermore, chamber 102 is preferably designed such that a variation of a film thickness of a deposited film is about±two percent of the thickness and composition of the film.

Single chamber system 100 also includes a plurality of first gaseous or elemental material sources 106-110, a plurality of second gaseous or elemental material sources 112-114, and shutters 118-126. Material sources 106-110 and 112-114 may be effusion cells, gas cells or e-beam sources. Single chamber system 100 also includes an oxygen source 116, such as an RF plasma source, a gas cell or a leak valve. First material sources 106-110 and oxygen source 116 may be used to form accommodating buffer layers and at least one of second material sources 112-114 may be used to form monocrystalline oxygen-doped compound semiconductor layers. In an illustrative embodiment, material source 106 includes a barium source, material source 108 includes a strontium source, and material source 110 includes a titanium source for the formation of a Sr_{z}Ba_{1-z}TiO₃ accommodating buffer layer. In another illustrative embodiment, material source 112 includes a gallium source and material source 114 includes an arsenic source for the formation of an oxygen-doped GaAs layer.

Chamber 102 may also include analytical tools such as Reflection High Energy Electron Diffraction (RHEED) to monitor the film crystal quality and composition during deposition (e.g., as the wafer rotates), a short wavelength ellipsometer to determine the thickness of the growing film and/or endpoint of a template formation process, or the like.

Chamber 102 also is configured to heat the structures to a desired temperature to form, for example, amorphous layer 402, illustrated in FIG. 4. In accordance with one aspect of this embodiment, chamber 102 also may include gas sources (not shown) to provide an overpressure of one or more of the film constituents during the anneal process. For example, if a GaAs film is exposed to the anneal process, chamber 102 includes an overpressure of As from, for example, a tertiary butyl arsenic (TBA), subliming arsenic, or arsine source.

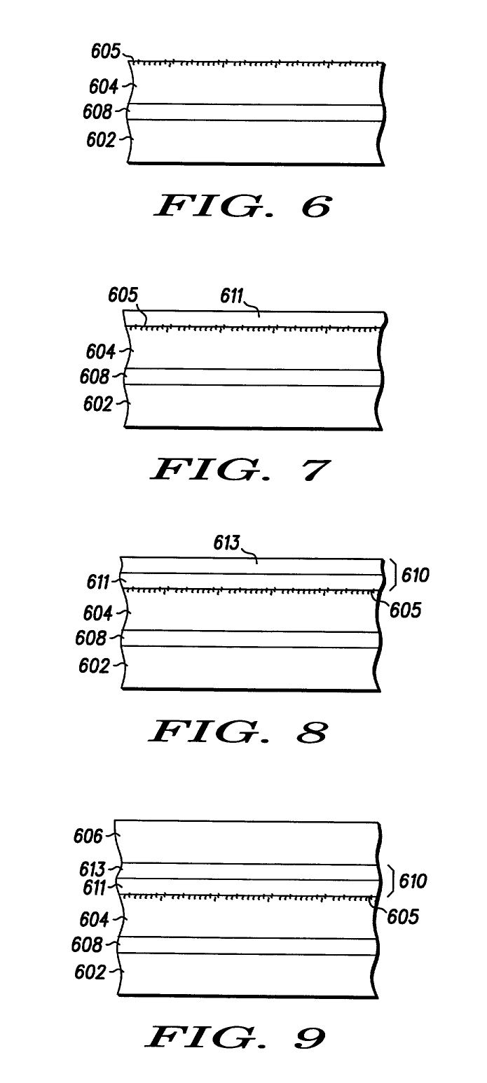

FIG. 5 illustrates a process 500 for forming the semiconductor structures using system 100. Process 500 includes a load step 510, an optional template formation step 520, an accommodating buffer layer formation step 530, an optional template formation step 540, a monocrystalline additional buffer layer growth step 550, a monocrystalline oxygen-doped material layer growth step 560, an optional anneal step 570, an optional monocrystalline layer growth step 580, and optional processing steps 590.

Referring to FIGS. 1 and 5, load substrates step 510 includes placing substrates such as silicon wafers into system 100, e.g., into chamber 102 via rotating manipulator 104, and sealing and evacuating chamber 102 to form a vacuum. In accordance with a preferred embodiment of the invention, the semiconductor substrate is a silicon wafer having a (100) orientation. The substrate is preferably oriented on axis or, at most, about 4° off axis toward (110). At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention.

Next, the wafers may be subjected to an optional template formation step 520. To epitaxially grow a monocrystalline oxide layer overlying the monocrystalline substrate, the native oxide layer must first be removed to expose the crystalline structure of the underlying substrate. The following process is preferably carried out by MBE in an MBE reactor, although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE reactor. In the case where strontium is used, the substrate is then heated to a temperature of at least 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of at least about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by MBE (step 530). The MBE process is initiated by opening shutters (e.g., shutters 120, 122 and 128) in chamber 102 to expose strontium, titanium and oxygen sources. The ratio of strontium and titanium is approximately 1:1. The partial pressure of oxygen is initially set at a minimum value to grow stochiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide interface layer.

After the strontium titanate layer has been grown to the desired thickness, the monocrystalline strontium titanate is capped by a template layer that is conducive to the subsequent growth of an epitaxial layer of a desired monocrystalline material (step 540). For example, for the subsequent growth of a monocrystalline oxygen-doped compound semiconductor material layer of gallium arsenide, the MBE growth of the strontium titanate monocrystalline layer can be capped by terminating the growth with 1-2 monolayers of strontium-oxygen, strontium, titanium, or titanium-oxygen. Following the formation of this capping layer, arsenic from material source 114 is deposited to form a Ti-As bond, a Ti-O-As bond or a Sr-O-As bond. Any of these form an appropriate template for deposition and formation of a gallium arsenide monocrystalline layer.

Following the formation of this capping layer, a monocrystalline oxygen-doped material layer is formed (step 560). Oxygen is partially removed from chamber 102 by oxygen adjustment system 132 to reduce the partial pressure of oxygen in chamber 102 depending on the desired extent to which a subsequent monocrystalline compound semiconductor is to be doped. The oxygen may be removed from chamber 102 by pumping the oxygen from the chamber, as in MBE systems, or by purging chamber 102 with inert gas such as argon, as in CVD systems. Arsenic is then deposited to form a Ti-As bond, a Ti-O-As bond or a Sr-O-As bond. Gallium is subsequently introduced to the reaction with the arsenic and oxygen-doped GaAs forms. Alternatively, gallium can be deposited on the capping layer to form a Sr-O-Ga bond, and arsenic is subsequently introduced with the gallium to form oxygen-doped GaAs. In one embodiment of the invention, the partial pressure of oxygen is reduced in chamber 102 before formation of the monocrystalline oxygen-doped material layer so that the monocrystalline oxygen-doped material layer has a graded oxygen content throughout the layer with the oxygen concentration decreasing from the bottom of the layer to the top. In another embodiment of the invention, the partial pressure of oxygen is reduced in chamber 102 during formation of the monocrystalline oxygen-doped material layer so that the monocrystalline oxygen-doped material layer has an even greater graded oxygen content. In a further embodiment of the invention, oxygen may be introduced into chamber 102 during formation of the monocrystalline oxygen-doped material layer so as to maintain a constant oxygen concentration throughout the layer. In yet another alternative embodiment of the invention, the partial pressure of oxygen in chamber 102 may be increased during formation of the monocrystalline oxygen-doped material layer so that the monocrystalline oxygen-doped material layer has a graded oxygen content, with the oxygen concentration increasing from the bottom of the layer to the top.

Following the formation of the oxygen-doped GaAs, the wafer may then be transferred to another deposition system, void or substantially void of oxygen, for the formation of a non-oxygen-doped GaAs layer (step 580).

Structure 300, illustrated in FIG. 3, can be formed by the process discussed above with the addition of an additional oxygen-doped buffer layer deposition step 550. The additional oxygen-doped buffer layer 302 is formed, using chamber 102, overlying the template layer before the deposition of the oxygen-doped compound semiconductor layer 206. If the additional oxygen-doped buffer layer is a monocrystalline material comprising a compound semiconductor superlattice, such a superlattice can be deposited, by MBE for example, on the template described above. If, instead, the additional oxygen-doped buffer layer is a monocrystalline material layer comprising a layer of germanium, the process above is modified to cap the strontium titanate monocrystalline layer with a final layer of either strontium or titanium and then by depositing germanium to react with the strontium or titanium. The oxygen-doped germanium buffer layer then can be deposited directly on this template. As described in reference to monocrystalline oxygen-doped material layer 206, the oxygen content of the additional oxygen-doped buffer layer may be varied within the layer by increasing or reducing the partial pressure of oxygen in chamber 102. In one embodiment of the invention, the partial pressure of oxygen is reduced before formation of additional oxygen-doped buffer layer 302 so that the layer has a graded oxygen content throughout the layer, with the oxygen concentration decreasing from the bottom of the layer to the top. In another embodiment of the invention, the partial pressure of oxygen is reduced during formation of additional oxygen-doped buffer layer 302 so that the layer has an even greater graded oxygen content. In a further embodiment of the invention, oxygen may be introduced into chamber 102 during formation of additional oxygen-doped buffer layer 302 so as to maintain a constant oxygen concentration throughout the layer. In yet another alternative embodiment of the invention, the partial pressure of oxygen may be increased during the formation of additional oxygen-doped buffer layer 302 so that the layer has a graded oxygen content with the oxygen concentration increasing from the bottom of the layer to the top.

Structure 400, illustrated in FIG. 4, may be formed in chamber 102 by growing an accommodating buffer layer, forming an amorphous oxide layer over the substrate, and growing the monocrystalline oxygen-doped material layer over the accommodating buffer layer, as described above. Alternatively, the additional oxygen-doped buffer layer may be grown prior to the annealing process. The accommodating buffer layer and the amorphous oxide layer are then exposed to an anneal process (step 570) sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 402. The wafer then can be transferred to another deposition system to form the monocrystalline material layer in an environment void or substantially void of oxygen.

In accordance with one aspect of this embodiment, layer 402 is formed by exposing substrate, the accommodating buffer layer, the amorphous oxide layer, and the monocrystalline oxygen-doped material layer to a rapid thermal anneal process in chamber 102 with a peak temperature of about 700° C. to about 1000° C. and a process time of about 5 seconds to about 10 minutes. However, other suitable anneal processes may be employed in chamber 102 to convert the accommodating buffer layer to an amorphous layer in accordance with the present invention. For example, laser annealing, electron beam annealing, or “conventional” thermal annealing processes (in the proper environment) may be used to form layer 402. An overpressure of arsenic may be employed to mitigate degradation of a GaAs layer during step 570.

Finally, step 590 may include any additional processing steps used in the manufacture of semiconductor devices. For example, step 590 may include deposition of insulating, conducting, dielectric, or other films. The additional processing steps may be performed within chamber 102 or in other suitable chambers.

The process described above illustrates a process for forming a semiconductor structure including a silicon substrate, an overlying oxide layer, and a monocrystalline oxygen-doped material layer comprising an oxygen-doped gallium arsenide compound semiconductor layer by the process of MBE. The process can also be carried out by the process CVD, MOCVD, MEE, ALE, PLD, or the like. Further, by a similar process, other monocrystalline accommodating buffer layers such as carbonates, alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline oxygen-doped material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline oxygen-doped material layer comprising compound semiconductors such as indium gallium arsenide, indium aluminum arsenide, or indium phosphide.

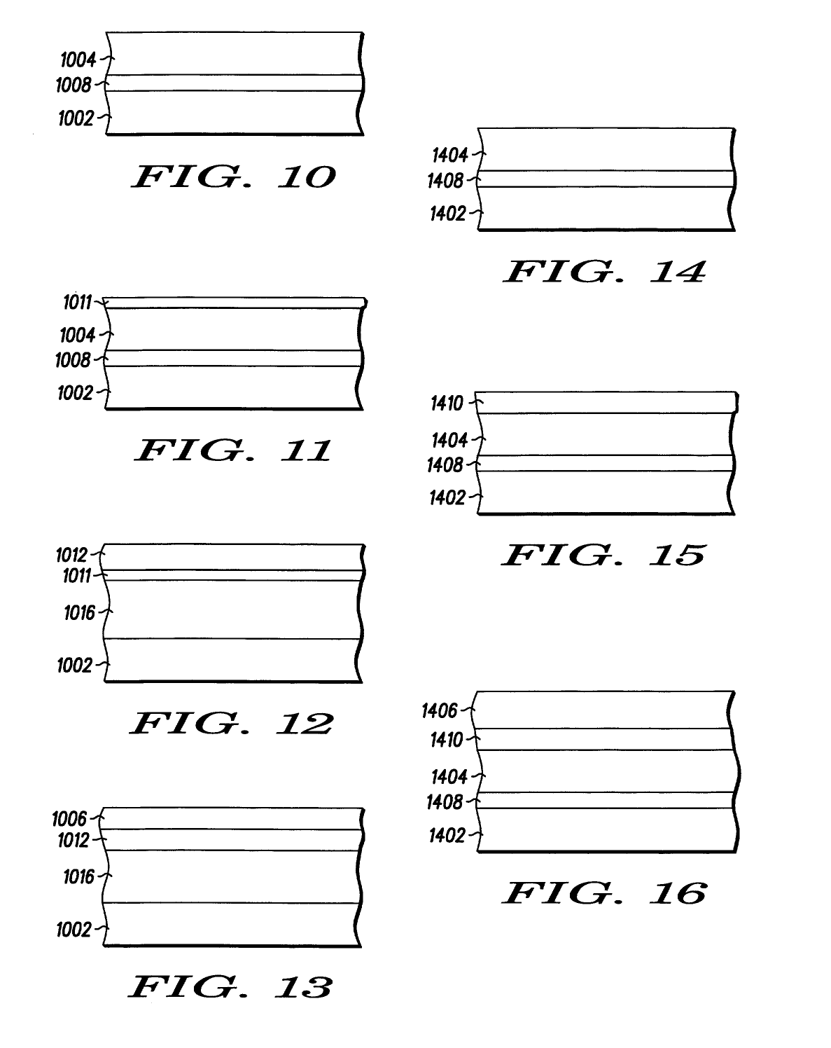

Alternatively, chamber 102 referred to in FIG. 1 may also comprise one or more material sources (not shown) that are configured to provide material for the formation of a template as described below with reference to FIGS. 6-16.

The formation of a device structure in accordance with another embodiment of the invention is illustrated schematically in cross-section in FIGS. 6-9. Like the previously described embodiments referred to in FIGS. 2-4, this embodiment of the invention involves the process of forming a compliant substrate utilizing the epitaxial growth of single crystal oxides, such as the formation of accommodating buffer layer 204 previously described with reference to FIGS. 2 and 3 and amorphous layer 402 previously described with reference to FIG. 4, and the formation of a template layer 212. However, the embodiment illustrated in FIGS. 6-9 utilizes a template that includes a surfactant to facilitate layer-by-layer monocrystalline material growth.

Turning now to FIGS. 1 and 6, an amorphous intermediate layer 608 is grown in chamber 102 on a substrate 602 at the interface between substrate 602 and a growing accommodating buffer layer 604, which is preferably a monocrystalline crystal oxide layer, by the oxidation of substrate 602 during the growth of layer 604 using the process earlier described with reference to FIGS. 1 and 5. Layer 604 is preferably a monocrystalline oxide material such as a monocrystalline layer of Sr_{z}Ba_{1-z}TiO₃, where z ranges from 0 to 1. However, layer 604 may also comprise any of those compounds previously described with reference to layer 204 in FIGS. 2-3 and any of those compounds previously described with reference to layer 402 in FIG. 3 which is formed from layers 204 and 210 referenced in FIGS. 2 and 3.

Layer 604 is grown with a strontium (Sr) terminated surface represented in FIG. 6 by hatched line 605 which is followed by the addition of a template layer 610 which includes a surfactant layer 611 and a capping layer 613, as illustrated in FIGS. 7 and 8. Surfactant layer 611 may comprise, but is not limited to, elements such as Al, In and Ga, but will be dependent upon the composition of layer 604 and the overlying layer of monocrystalline material for optimal results. In one exemplary embodiment, aluminum (Al) is used for surfactant layer 611 and functions to modify the surface and surface energy of layer 604. Preferably, surfactant layer 611 is epitaxially grown, to a thickness of one to two monolayers, over layer 604 as illustrated in FIG. 7 by way of MBE, although other epitaxial processes may also be performed including CVD, MOCVD, MEE, ALE, PLD, or the like.

Surfactant layer 611 is then exposed to a Group V element such as arsenic, for example, to form capping layer 613 as illustrated in FIG. 8. Surfactant layer 611 may be exposed to a number of materials to create capping layer 613 such as elements which include, but are not limited to, As, P, Sb and N. Surfactant layer 61 and capping layer 63 combine to form template layer 610.

Monocrystalline oxygen-doped material layer 606, which in this example is a compound semiconductor such as GaAs, is then deposited via MBE, CVC, MOCVD, MEE, ALE, PLD, or the like to form the structure illustrated in FIG. 9.

Turning now to FIGS. 10-13, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 1004 such as a monocrystalline oxide layer is first grown in chamber 102 on a substrate layer 1002, such as silicon, with an amorphous interface layer 1008 as illustrated in FIG. 10, using the process earlier described with reference to FIGS. 1 and 5. Monocrystalline oxide layer 1004 may be comprised of any of those materials previously discussed with reference to layer 204 in FIGS. 2 and 3, while an amorphous interface layer 1008 is preferably comprised of any of those materials previously described with reference to the layer 210 illustrated in FIGS. 1 and 2. Substrate 1002, although preferably silicon, may also comprise any of those materials previously described with reference to substrate 202 in FIGS. 2-4.

Next, silicon layer 1011 is deposited over monocrystalline oxide layer 1004 via MBE, CVD, MOCVD, MEE, ALE, PLD, or the like as illustrated in FIG. 11 with a thickness of a few hundred Angstroms but preferably with a thickness of about 50 Angstroms. Monocrystalline oxide layer 1004 preferably has a thickness of about 20 to 100 Angstroms.

Rapid thermal annealing is then conducted in chamber 102 in the presence of a carbon source (not shown in FIG. 1) such as acetylene or methane, for example at a temperature within a range of about 800° C. to 1000° C. to form a capping layer 1012 and a silicate amorphous layer 1016. However, other suitable carbon sources may be used as long as the rapid thermal annealing step functions to amorphize the monocrystalline oxide layer 1004 into a silicate amorphous layer 1016 and carbonize the top silicon layer 1011 to form capping layer 1012 which in this example would be a silicon carbide (SiC) layer as illustrated in FIG. 12. The formation of amorphous layer 1016 is similar to the formation of layer 402 illustrated in FIG. 4 and may comprise any of those materials described with reference to layer 402 in FIG. 4 but the preferable material will be dependent upon the capping layer 1012 used for silicon layer 1011.

Finally, a monocrystalline oxygen-doped compound semiconductor layer 1006, such as oxygen-doped gallium nitride (GaN) is grown over the SiC surface by way of MBE, CVD, MOCVD, MEE, ALE, PLD, or the like to form a high quality oxygen-doped compound semiconductor material. More specifically, the deposition of GaN and GaN-based systems such as GaInN and AlGaN will result in the formation of dislocation nets confined at the silicon/amorphous region. The resulting nitride containing oxygen-doped compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an interface single crystal oxide layer that is amorphisized to form a silicate layer which adsorbs the strain between the layers. Moreover, unlike past use of a SiC substrate, this embodiment of the invention is not limited by wafer size which is usually less than 50 mm in diameter for prior art SiC substrates.

The formation of the oxygen-doped GaN layer may be followed by the subsequent growth of a high quality non-oxygen-doped GaN material layer in a separate deposition system. The monolithic integration of nitride containing semiconductor compounds containing group III-V nitrides and silicon devices can be used for high temperature RF applications and opto-electronics. GaN systems have particular use in the photonic industry for the blue/green and UV light sources and detection. High brightness light emitting diodes (LEDs) and lasers may also be formed within the GaN system.

FIGS. 14-16 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 14 includes a monocrystalline substrate 1402, an amorphous interface layer 1408 and an accommodating buffer layer 1404. Amorphous interface layer 1408 is formed on substrate 1402 at the interface between substrate 1402 and accommodating buffer layer 1404 as previously described with reference to FIGS. 2 and 3. Amorphous interface layer 1408 may comprise any of those materials previously described with reference to amorphous interface layer 210 in FIGS. 2 and 3. Substrate 202 is preferably silicon but may also comprise any of those materials previously described with reference to substrate 202 in FIGS. 2-4.

A template layer 1410 is deposited over accommodating buffer layer 1404 as illustrated in FIG. 15 and preferably comprises a thin layer of Zintl type phase material composed of metals and metalloids having a great deal of ionic character. As in previously described embodiments, template layer 1410 is deposited in chamber 102 referred to in FIG. 1 by way of MBE, CVD, MOCVD, MEE, ALE, PLD, or the like to achieve a thickness of one monolayer. Template layer 1420 functions as a “soft” layer with non-directional bonding but high crystallinity which absorbs stress build up between layers having lattice mismatch. Materials for template 1410 may include, but are not limited to, materials containing Si, Ga, In, and Sb such as, for example, SrAl₂, (MgCaYb)Ga₂, (Ca,Sr,EuYb)In₂, BaGe₂As, and SrSn₂As₂.

A monocrystalline oxygen-doped material layer 1406 is epitaxially grown over template layer 1410 to achieve the final structure illustrated in FIG. 16. As a specific example, an SrAl₂ layer may be used as template layer 1410 and an appropriate monocrystalline oxygen-doped material layer 1406 such as an oxygen-doped compound semiconductor material GaAs is grown over the SrAl₂. The Al-Ti (from the accommodating buffer layer of Sr_{z}Ba_{1-z}TiO₃ where z ranges from 0 to 1) bond is mostly metallic while the Al-As (from the GaAs layer) bond is weakly covalent. The Sr participates in two distinct types of bonding with part of its electric charge going to the oxygen atoms in the lower accommodating buffer layer 1404 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 1410 as well as on the interatomic distance. In this example, Al assumes an sp³ hybridization and can readily form bonds with monocrystalline oxygen-doped material layer 1406, which in this example, comprises oxygen-doped compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes apparatus and methods for fabricating material layers which form semiconductor structures, devices and integrated circuits including other layers such as metal and non-metal layers. More specifically, the invention includes apparatus and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline oxygen-doped semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 mm in diameter and possibly at least approximately 300 mm.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. An apparatus for forming a semiconductor structure comprising:
a chamber;
a plurality of first material sources positioned at least partially within said chamber and configured to provide materials for the formation of a monocrystalline accommodating buffer layer on a substrate, said plurality of first material sources comprising an oxygen source;
at least one second material source positioned at least partially within said chamber and configured to provide material for the formation of a monocrystalline oxygen-doped material layer overlying said monocrystalline accommodating buffer layer; and
an oxygen-adjustment mechanism configured to adjust the partial pressure of oxygen in said chamber.

2. The apparatus of claim 1, further comprising a manipulator positioned at least partially within said chamber and configured to hold a substrate.

3. The apparatus of claim 1, wherein said substrate is comprised of silicon.

4. The apparatus of claim 1, wherein the accommodating buffer layer is selected from the group consisting of alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

5. The apparatus of claim 1, wherein said monocrystalline oxygen-doped material layer comprises an oxygen-doped compound semiconductor.

6. The apparatus of claim 1, wherein said monocrystalline oxygen-doped material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

7. The apparatus of claim 1, wherein said monocrystalline oxygen-doped material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, and lead sulfide selenide.

8. The apparatus of claim 1, further comprising at least one template material source positioned at least partially within said chamber and configured to provide materials for the formation of a template layer overlying said accommodating buffer layer.

9. The apparatus of claim 8, wherein said template layer comprises a Zintl-type phase material.

10. The apparatus of claim 9, wherein said Zintl-type phase material comprises at least one of SrAl₂, (MgCaYb)Ga₂, (Ca,Sr,EuYb)In₂, BaGe₂As, and SrSn₂As₂.

11. The apparatus of claim 8, wherein said template layer comprises a surfactant material.

12. The apparatus of claim 11, wherein said surfactant material comprises at least one of Al, Bi, In, and Ga.

13. The apparatus of claim 11, wherein said template layer further comprises a capping layer.

14. The apparatus of claim 13, wherein said capping layer is formed by exposing said surfactant material to a cap-inducing material.

15. The apparatus of claim 14, wherein said cap-inducing material comprises at least one of As, P, Sb, and N.

16. The apparatus of claim 8, wherein said template layer comprises a capping layer formed of about 1-10 monolayers of one of a material M-N and a material M-O-N, wherein M is selected from at least one of Zr, Hf, Sr, and Ba and N is selected from at least on of As, P, Ga, Al, and In.

17. The apparatus of claim 1, wherein said monocrystalline accommodating buffer layer is formed of a monocrystalline oxide material and said chamber is configured to heat treat said monocrystalline oxide material to convert said monocrystalline oxide material to an amorphous oxide.

18. The apparatus of claim 1, further comprising at least one additional buffer layer material source positioned at least partially within said chamber and configured to provide material for the formation of an additional monocrystalline oxygen-doped buffer layer overlying said accommodating buffer layer and underlying said monocrystalline oxygen-doped material layer.

19. The apparatus of claim 18, wherein said additional monocrystalline oxygen-doped buffer layer comprises at least one of a semiconductor material, a compound semiconductor material, a metal and a non-metal.

20. The apparatus of claim 18, wherein said additional monocrystalline oxygen-doped buffer layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, and lead sulfide selenide.

21. The apparatus of claim 1, wherein said substrate is approximately 300 mm in diameter.

22. The apparatus of claim 1, said oxygen-adjustment mechanism configured to maintain an approximately constant partial pressure of oxygen in said chamber during formation of said monocrystalline oxygen-doped material layer.

23. The apparatus of claim 1, said oxygen-adjustment mechanism configured to increase said partial pressure of oxygen during formation of said monocrystalline oxygen-doped material layer.

24. The apparatus of claim 1, said oxygen-adjustment mechanism configured to decrease said partial pressure of oxygen during formation of said monocrystalline oxygen-doped material layer.

25. A method of forming a semiconductor structure, said method comprising:
providing a monocrystalline substrate in a chamber;
forming in said chamber a monocrystalline accommodating buffer layer overlying said monocrystalline substrate; and
forming in said chamber a monocrystalline oxygen-doped material layer overlying said monocrystalline accommodating buffer layer.

26. The method of claim 25, wherein said monocrystalline substrate comprises silicon.

27. The method of claim 25, wherein said monocrystalline accommodating buffer layer is selected from the group consisting of alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

28. The method of claim 25, wherein said monocrystalline oxygen-doped material layer comprises an oxygen-doped compound semiconductor.

29. The method of claim 25, wherein said monocrystalline oxygen-doped material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

30. The method of claim 25, wherein said monocrystalline oxygen-doped material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, and lead sulfide selenide.

31. The method of claim 25, further comprising forming in said chamber an amorphous oxide interface layer between said monocrystalline substrate and said monocrystalline accommodating buffer layer.

32. The method of claim 25, further comprising forming in said chamber a template layer overlying said accommodating buffer layer and underlying said monocrystalline oxygen-doped material layer.

33. The method of claim 32, wherein said template layer comprises a Zintl-type phase material.

34. The method of claim 33, wherein said Zintl-type phase material comprises at least one of SrAl₂, (MgCaYb)Ga₂, (Ca,Sr,EuYb)In₂, BaGe₂As, and SrSn₂As₂.

35. The method of claim 32, wherein said template layer comprises a surfactant material.

36. The method of claim 35, wherein said surfactant material comprises at least one of Al, Bi, In, and Ga.

37. The method of claim 35, wherein said template layer further comprises a capping layer.

38. The method of claim 37, wherein said capping layer is formed by exposing said surfactant material to a cap-inducing material.

39. The method of claim 38, wherein said cap-inducing material comprises at least one of As, P, Sb, and N.

40. The method of claim 32, wherein said template layer comprises a capping layer formed of about 1-10 monolayers of one of a material M-N and a material M-O-N, wherein M is selected from at least one of Zr, Hf, Sr, and Ba and N is selected from at least on of As, P, Ga, Al, and In.

41. The method of claim 25, wherein said monocrystalline accommodating buffer layer is formed of a monocrystalline oxide material and said method further comprises heat treating in said chamber said monocrystalline oxide material to convert said monocrystalline oxide material to an amorphous oxide.

42. The method of claim 25, further comprising forming in said chamber an additional monocrystalline oxygen-doped buffer layer overlying said accommodating buffer layer and underlying said monocrystalline oxygen-doped material layer.

43. The method of claim 25, wherein said additional monocrystalline oxygen-doped buffer layer comprises at least one of a semiconductor material, a compound semiconductor material, a metal and a non-metal.

44. The method of claim 25, wherein said additional monocrystalline oxygen-doped buffer layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, and lead sulfide selenide.

45. The method of claim 25, wherein each of the steps of forming comprises forming by a process selected from the group consisting of MBE, MOCVD, MEE, CVD, PLD, and ALE.

46. The method of claim 25, wherein said monocrystalline substrate is approximately 300 mm in diameter.

47. A method of forming a semiconductor structure, said method comprising:
loading a monocrystalline substrate into a chamber;
activating a plurality of first material sources to form in said chamber a monocrystalline accommodating buffer layer overlying said monocrystalline substrate, wherein at least one of said plurality of first material sources comprises an oxygen source which effects an oxygen pressure in said chamber;
adjusting said oxygen pressure in said chamber; and
activating at least one second material source to form in said chamber a monocrystalline oxygen-doped material layer overlying said monocrystalline accommodating buffer layer.

48. The method of claim 47, wherein said monocrystalline substrate comprises silicon.

49. The method of claim 47, wherein said monocrystalline accommodating buffer layer is selected from the group consisting of alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide.

50. The method of claim 47, wherein said monocrystalline oxygen-doped material layer comprises an oxygen-doped compound semiconductor.

51. The method of claim 47, wherein said monocrystalline oxygen-doped material layer comprises a material selected from one of: Group III-V compound semiconductors, mixed III-V compounds, Group II-VI compound semiconductors, mixed II-VI compounds, Group IV-VI compound semiconductors, and mixed IV-VI compounds.

52. The method of claim 47, wherein said monocrystalline oxygen-doped material layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, and lead sulfide selenide.

53. The method of claim 47, further comprising forming in said chamber an amorphous oxide interface layer between said monocrystalline substrate and said monocrystalline accommodating buffer layer.

54. The method of claim 47, further comprising activating at least one template material source to form in said chamber a template layer overlying said accommodating buffer layer and underlying said monocrystalline oxygen-doped material layer.

55. The method of claim 54, wherein said template layer comprises a Zintl-type phase material.

56. The method of claim 55, wherein said Zintl-type phase material comprises at least one of SrAl₂, (MgCaYb)Ga₂, (Ca,Sr,EuYb)In₂, BaGe₂As, and SrSn₂As₂.

57. The method of claim 54, wherein said template layer comprises a surfactant material.

58. The method of claim 57, wherein said surfactant material comprises at least one of Al, Bi, In, and Ga.

59. The method of claim 57, wherein said template layer further comprises a capping layer.

60. The method of claim 59, wherein said capping layer is formed by exposing said surfactant material to a cap-inducing material.

61. The method of claim 60, wherein said cap-inducing material comprises at least one of As, P, Sb, and N.

62. The method of claim 54, wherein said template layer comprises a capping layer formed of about 1-10 monolayers of one of a material M-N and a material M-O-N, wherein M is selected from at least one of Zr, Hf, Sr, and Ba and N is selected from at least on of As, P, Ga, Al, and In.

63. The method of claim 47, further comprising heat treating in said chamber said monocrystalline accommodating buffer layer to convert said monocrystalline accommodating buffer layer to an amorphous oxide material layer.

64. The method of claim 47, further comprising activating at least one additional monocrystalline buffer layer material source positioned at least partially within said chamber to form an additional monocrystalline oxygen-doped buffer layer overlying said accommodating buffer layer and underlying said monocrystalline oxygen-doped material layer.

65. The method of claim 64, wherein said additional monocrystalline oxygen-doped buffer layer comprises at least one of a semiconductor material, a compound semiconductor material, a metal and a non-metal.

66. The method of claim 64, wherein said additional monocrystalline oxygen-doped buffer layer comprises a material selected from one of: gallium arsenide, gallium indium arsenide, gallium aluminum arsenide, indium phosphide, cadmium sulfide, cadmium mercury telluride, zinc selenide, zinc sulfur selenide, lead selenide, lead telluride, and lead sulfide selenide.

67. The method of claim 47, wherein each of the steps of forming comprises forming by a process selected from the group consisting of MBE, MOCVD, MEE, CVD, PLD, and ALE.

68. The method of claim 47, wherein said monocrystalline substrate is approximately 300 mm in diameter.

69. The method of claim 47, wherein said adjusting said oxygen pressure in said chamber comprises effecting a constant oxygen pressure in said chamber during said activating at least one second material source.

70. The method of claim 47, wherein said adjusting said oxygen pressure in said chamber comprises decreasing said oxygen pressure during said activating at least one second material source.

71. The method of claim 47, wherein said adjusting said oxygen pressure in said chamber comprises increasing said oxygen pressure during said activating at least one second material source.
